(19) United States
(12) Patent Application Publication
(10) Pub. No.: US 2012/0155192 A1
(43) Pub. Date: Jun. 21, 2012

(54) SEMICONDUCTOR MEMORY DEVICES AND METHODS OF TESTING THE SAME

(75) Inventor: Sang Joon Ryu, Asan-si (KR)

(73) Assignee: SAMSUNG ELECTRONICS CO., LTD., Suwon-si (KR)

(21) Appl. No.: 13/316,921

(22) Filed: Dec. 12, 2011

(30) Foreign Application Priority Data
Dec. 17, 2010 (KR) 10-2010-0130316

(51) Int. Cl. G11C 29/00; G11C 7/10

(52) U.S. Cl. 365/189.05; 365/201

(57) ABSTRACT

A semiconductor memory device and a method of testing the same are provided. The semiconductor memory device includes a memory cell array including a plurality of memory cells each of which stores at least one bit of data; an output terminal configured to transmit output data; and a data output circuit configured to be connected with the output terminal, to divide a cycle of a clock signal into at least two periods, to transmit the output data to the output terminal only during a particular period among the at least two periods, and to put the output terminal into a state of high impedance during the remaining periods other than the particular period among the at least two periods.

### CROSS-REFERENCE TO RELATED APPLICATIONS

This application claims priority under 35 U.S.C. §119(a) from Korean Patent Application No. 10-2010-0130316 filed on Dec. 17, 2010, the disclosure of which is hereby incorporated by reference in its entirety.

### BACKGROUND

1. Field

The present inventive concepts relate to a semiconductor device, and more particularly, to a semiconductor memory device, a memory system including the device, and methods of manufacturing the same.

2. Description of Related Art

Manufacturing products in which at least two and up to four or eight layers of dynamic random access memory (DRAM) or flash memory are stacked up and assembled into a single package can take significant time and effect the ability to meet the demand on high capacity. Since each layer in a package is tested individually, test time is two to four times longer when two to four layers of the same memories are stacked up in the package than when a single layer is in the package.

Accordingly, an approach for efficiently testing a semiconductor device including a plurality of chips is desired to reduce the test time and cost.

### SUMMARY

According to some embodiments of present inventive concepts, there is provided a semiconductor memory device including a memory cell array including a plurality of memory cells each of which stores at least one bit of data; an output terminal configured to output output data; and a data output circuit configured to be connected with the output terminal, to divide a cycle of a clock signal into at least two periods, to output the output data to the output terminal only during a particular period among the at least two periods, and to put the output terminal into a state of high impedance during the remaining period other than the particular period among the at least two periods.

The data output circuit can include a data masking control circuit configured to generate a masking control signal which is enabled during the particular period and is disabled during the remaining period in response to the clock signal and a masking signal; and a data output buffer configured to output the output data to the output terminal or put the output terminal into the state of high impedance in response to the clock signal and the masking control signal.

According to other embodiments of present inventive concepts, there is provided a semiconductor memory device including a plurality of semiconductor chips and an external terminal configured to output a signal output from each of the semiconductor chips to an external source. Each of the semiconductor chips includes an output terminal configured to output output data; and a data output circuit configured to be connected with the output terminal, to divide a cycle of a first clock signal into a plurality of periods, to output the output data to the output terminal only during a particular period among the plurality of periods, and to put the output terminal into a state of high impedance during the remaining period other than the particular period among the plurality of periods.

The output terminals of the respective semiconductor chips can be connected in common with the output terminal or can be connected with independent external terminals, respectively.

Each of the semiconductor chips can further include a mode register set (MRS) circuit configured to set a test mode.

The data output circuit can output the output data to the output terminal only during the particular period and put the output terminal into the state of high impedance during the remaining period in response to a masking control signal in the test mode. The data output circuit can output the output data to the output terminal during a full period of a cycle of the first clock signal in a non-test mode.

According to further embodiments of present inventive concepts, there is provided a method of testing a semiconductor memory device which includes a plurality of memory chips and an external terminal connected in common with the plurality of memory chips.

The method includes dividing a cycle of a clock signal into a plurality of periods; and outputting output data of each of the memory chips to an output terminal of each memory chip only during a particular period among the plurality of periods and putting the output terminal into a state of high impedance during the remaining period other than the particular period among the plurality of periods.

In an aspect of inventive concepts, a semiconductor memory device includes a memory cell array comprising a plurality of memory cells each of which stores at least one bit of data, an output terminal configured to output output data, and a data output circuit configured to be connected with the output terminal, to divide a cycle of a clock signal into at least two periods, to output the output data to the output terminal only during a particular period of the at least two periods, and to put the output terminal into a state of high impedance during the remaining periods other than the particular period of the at least two periods.

In an embodiment, the data output circuit includes a data masking control circuit configured to generate a masking control signal which is enabled during the particular period and is disabled during the remaining period in response to the clock signal and a masking signal, a data output buffer configured to output the output data to the output terminal or put the output terminal into the state of high impedance in response to the clock signal and the masking control signal.

In an embodiment, the data output circuit includes a data masking control circuit configured to generate a masking control signal which is enabled during the particular period and is disabled during the remaining period in response to the clock signal and a masking signal, a data output buffer configured to output the output data to the output terminal in response to the clock signal, a switch configured to be positioned between the data output buffer and the output terminal and to be closed or opened in response to the masking control signal.

In an embodiment, the masking signal includes a first masking signal and a second masking signal, and the data masking control circuit includes a first AND element configured to perform an AND operation on the clock signal and the first masking signal, a second AND element configured to perform an AND operation on an inverted signal of the clock signal and the second masking signal, and a first OR element configured to perform an OR operation on an output signal of the first AND element and an output signal of the second AND element and to output the mask control signal.

In an embodiment, the clock signal is a first clock signal, the masking signal includes a first, second, third and fourth masking signals, and the data masking control circuit includes a first AND element configured to perform an AND operation on the clock signal and the first masking signal, a second AND element configured to perform an AND operation on an inverted signal of the clock signal and the second masking signal, a first OR element configured to perform an OR operation on an output signal of the first AND element and an output signal of the second AND element, a third AND element configured to perform an AND operation on a second clock signal and the third masking signal, a fourth AND element configured to perform an AND operation on an inverted signal of the second clock signal and the fourth masking signal, a second OR element configured to perform an OR operation on an output signal of the third AND element and an output signal of the fourth AND element, and a third OR element configured to perform an OR operation on an output signal of the first OR element and an output signal of the second OR element and to output the mask control signal.

In an embodiment, the semiconductor memory device further includes a mode register set (MRS) circuit configured to set the masking signal.

In an embodiment, the data output circuit outputs the output data to the output terminal only during the particular period and puts the output terminal into the state of high impedance during the remaining periods in response to the masking control signal in a test mode and the data output circuit outputs the output data to the output terminal during a full period of a cycle of the clock signal in a non-test mode.

In an aspect of inventive concepts, a semiconductor memory device is provided that includes a plurality of semiconductor chips and an external terminal configured to output a signal output from each of the semiconductor chips to an external circuit, wherein each of the semiconductor chips includes: an output terminal configured to output output data and a data output circuit configured to be connected with the output terminal, to divide a cycle of a clock signal into a plurality of periods, to output the output data to the output terminal only during a particular period among the plurality of periods, and to put the output terminal into a state of high impedance during the remaining periods other than the particular period among the plurality of periods.

In an embodiment, the output terminals of the respective semiconductor chips are connected in common with at least one of the external terminal or independent external output terminals.

In an embodiment, each of the semiconductor chips further includes a mode register set (MRS) circuit configured to set a test mode wherein the data output circuit outputs the output data to the output terminal only during the particular period and puts the output terminal into the state of high impedance during the remaining period in response to a masking control signal in the test mode and the data output circuit outputs the output data to the output terminal during a full period of a cycle of the clock signal in a non-test mode.

In an embodiment, the data output circuit includes a data masking control circuit configured to generate a masking control signal which is enabled during the particular period and is disabled during the remaining period in response to the first clock signal and a masking signal and a data output buffer configured to output the output data to the output terminal or put the output terminal into the state of high impedance in response to the clock signal and the masking control signal.

In an embodiment, the semiconductor chips comprise first through n-th memory chips where “n” is 2 or an integer greater than 2, and a data output circuit of each of the first through n-th memory chips outputs data of a memory chip, which includes the data output circuit, only during a particular period among first through n-th periods into which each cycle of the clock signal is divided and puts an output terminal of the memory chip into the state of high impedance during the remaining periods.

In an embodiment, “n” is 2 and each of the clock cycles is divided into a first and second period, a data output circuit of the first memory chip outputs data of the first memory chip only during the first period of each cycle of the clock signal, and a data output circuit of the second memory chip outputs data of the second memory chip only during the second period of each cycle of the clock signal.

In an embodiment, “n” is 4 and each of the clock cycles is divided into first through fourth periods, a data output circuit of the first memory chip outputs data of the first memory chip only during the first period of each cycle of the clock signal, a data output circuit of the second memory chip outputs data of the second memory chip only during the second period of each cycle of the clock signal, a data output circuit of the third memory chip outputs data of the third memory chip only during the third period of each cycle of the clock signal, and a data output circuit of the fourth memory chip outputs data of the fourth memory chip only during the fourth period of each cycle of the clock signal.

In an aspect of inventive concepts, a test system is provided that includes at least one of the semiconductor memory devices described herein, wherein the test system includes a tester configured to receive data output through the external terminal of the semiconductor memory device and compare the data with reference data to test the at least one semiconductor memory device.

In an aspect of inventive concepts, a memory system is provided that that includes at least one of the semiconductor memory devices described herein, wherein the memory system includes a memory controller configured to control the semiconductor memory device.

In an aspect of inventive concepts, a method is provided for testing a semiconductor memory device which includes a plurality of memory chips, the method including the operations of dividing a cycle of a clock signal into a plurality of periods and outputting output data of each of the memory chips to an output terminal of each memory chip only during a particular period among the plurality of periods and putting the output terminal into a state of high impedance during the remaining periods other than the particular period among the plurality of periods.

In an embodiment, the plurality of periods includes two periods including a first period and second period, and wherein the operation of outputting the output data and putting the output terminal into the state of high impedance includes: outputting output data of a first memory chip only during the first period of each cycle of the clock signal and outputting output data of a second memory chip only during the second period of each cycle of the clock signal.

In an embodiment, the plurality of periods includes four periods including first through fourth periods, and wherein the operation of outputting the output data and putting the output terminal into the state of high impedance includes: outputting output data of a first memory chip only during the first period of each cycle of the first clock signal, outputting output data of a second memory chips only during the second period of each cycle of the clock signal, outputting output data of a third memory chip only during the third period of each cycle of the clock signal, and outputting output data of a fourth memory chip only during the fourth period of each cycle of the clock signal.

In an embodiment a tester receives data output through an external terminal of the semiconductor memory device and compares the data with reference data.

In an embodiment, the clock signal is a signal received from a source external to the semiconductor memory device or a signal generated within the semiconductor memory device.

In an aspect of inventive concepts, a semiconductor memory device includes a plurality of semiconductor chips, each of which stores at least one bit of data and wherein each of the semiconductor chips is connected to a corresponding control circuit and a corresponding output terminal through which stored data of the semiconductor chip can be transmitted, a common output terminal configured to transmit data from each of the output terminals of the plurality of semiconductor chips, wherein each of the control circuits is configured to permit transmission of data from the corresponding output terminal during a corresponding transmission period of a plurality of periods of a clock cycle, wherein the control circuit blocks transmission of data from the corresponding output terminal during all of the transmission periods corresponding to the other control circuits.

In an embodiment, the control circuits are configured to block transmission of data from the corresponding output terminal by putting the corresponding output terminal into a state of high impedance.

In an embodiment, the control circuits are configured to block transmission of data from the corresponding output terminal by activating a switch to disconnect the corresponding output terminal from the common output terminal.

In an embodiment, the plurality of semiconductor chips comprise stacked memory cells.

In an embodiment, each of the corresponding transmission periods corresponds to a phase of the clock cycle.

In an embodiment, each of the phases corresponds to one of a low or high state of the clock cycle.

### BRIEF DESCRIPTION OF THE DRAWINGS

The accompanying drawings are included to provide a further understanding of the inventive concepts, and are incorporated in, and constitute a part of, this specification. The drawings illustrate exemplary embodiments of inventive concepts and, together with the description, serve to explain principles of the inventive concepts. In the drawings:

FIG. 1 is a schematic block diagram of the structure of a semiconductor memory device according to an aspect of present inventive concepts;

FIG. 2A is a diagram showing the connection of output terminals of the semiconductor memory device illustrated in FIG. 1;

FIG. 2B is a diagram showing the multi-chip package structure of the semiconductor memory device illustrated in FIG. 1;

FIG. 3 is a diagram of the structure of a data output circuit according to an aspect of present inventive concepts;

FIG. 4 is a timing chart showing the operation of the data output circuit illustrated in FIG. 3;

FIG. 5 is a diagram of the structure of a data output circuit according to an aspect of present inventive concepts;

FIG. 6 is a detailed diagram of the structure of a semiconductor memory device according to an aspect of present inventive concepts;

FIG. 7A is a timing chart of the operation of the semiconductor memory device illustrated in FIG. 6;

FIG. 7B is a timing chart of the operation of a semiconductor memory device;

FIG. 8 is a diagram of the structure of a data output circuit according to an aspect of present inventive concepts;

FIG. 9 is a timing chart of the operation of the data output circuit illustrated in FIG. 8;

FIGS. 10 and 11 are a table and a timing chart for explaining the operation of a semiconductor memory device, which includes four memory chips, according to an aspect of present inventive concepts; and

FIG. 12 is a schematic diagram of a memory system according to an aspect of present inventive concepts.

### DETAILED DESCRIPTION OF THE EMBODIMENTS

Embodiments of inventive concepts now will be described more fully hereinafter with reference to the accompanying drawings, in which embodiments of the inventive concepts are shown. An aspect of inventive concepts can, however, be embodied in many different forms and should not be construed as limited to the embodiments set forth herein. Rather, these embodiments are provided so that this disclosure will convey the scope of the inventive concepts to those skilled in the art. In the drawings, the size and relative sizes of layers and regions may be exaggerated for clarity. Like numbers refer to like elements throughout.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein, the term “and/or” includes any and all combinations of one or more of the associated listed items and may be abbreviated as “/”.

It will be understood that, although the terms first, second, etc. may be used herein to describe various elements, these elements should not be limited by these terms. These terms are only used to distinguish one element from another. For example, a first signal could be termed a second signal, and, similarly, a second signal could be termed a first signal without departing from the teachings of the disclosure.

The terminology used herein is for the purpose of describing particular embodiments only and is not intended to be limiting of the inventive concepts. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which the inventive concepts belong. It will be further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein.

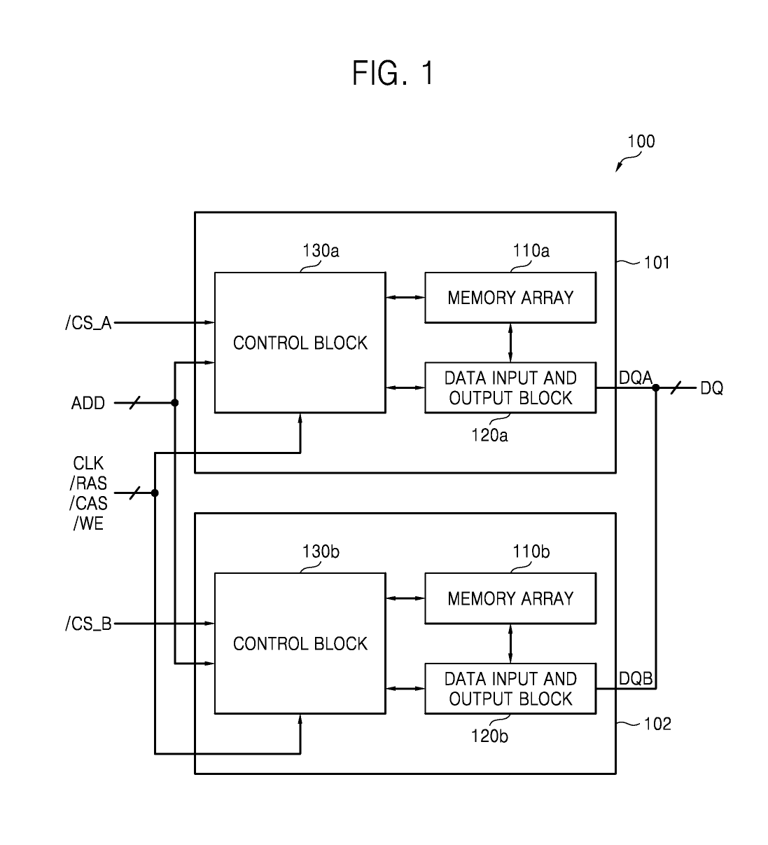

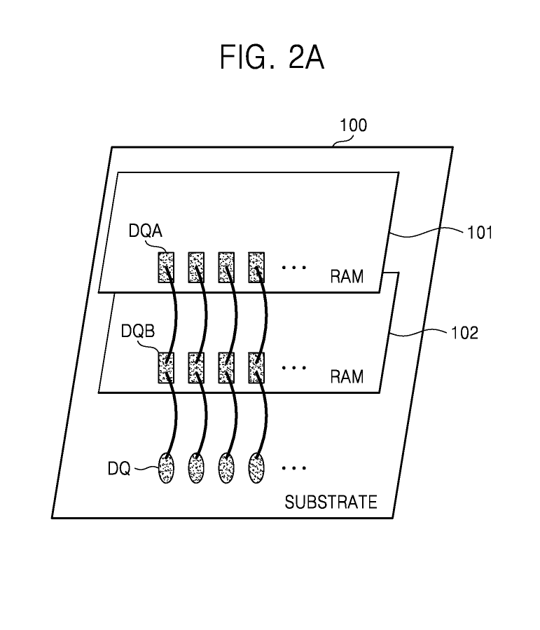

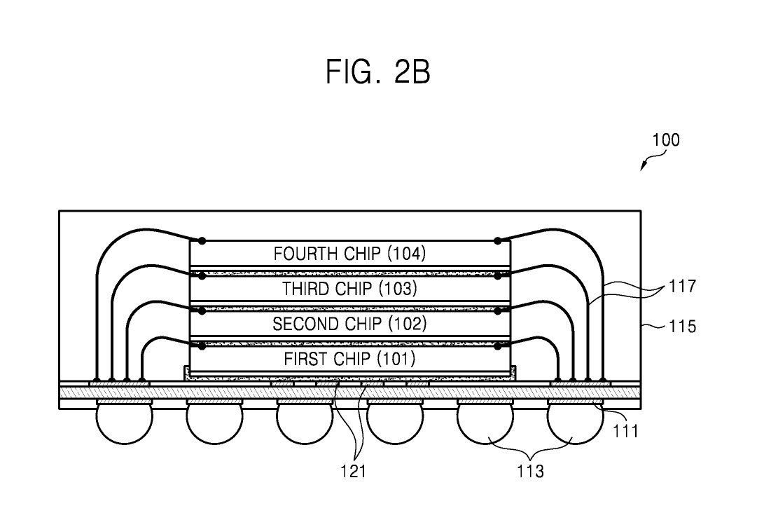

FIG. 1 is a schematic block diagram of the structure of a semiconductor memory device 100 according to some embodiments of present inventive concepts. FIG. 2A is a diagram showing the connection of output terminals of the semiconductor memory device 100 illustrated in FIG. 1. FIG. 2B is a diagram showing the multi-chip package structure of the semiconductor memory device 100.

Referring to FIGS. 1 through 2B, the semiconductor memory device 100 can include a plurality of (at least two) memory chips 101, 102, 103, and 104 which can be packaged in a stack structure as shown in FIG. 2B. In other words, the semiconductor memory device 100 may be a multi-chip package (MCP) memory device with a stack structure.

Referring to FIG. 1, the semiconductor memory device 100 includes a first memory chip 101 and a second memory chip 102. Each of the memory chips 101 and 102 includes a memory array 110a or 110b, a data input and output block 120a or 120b, and a control block 130a or 130b.

The memory arrays 110a and 110b can include a plurality of memory cells each of which can store at least one bit of data.

The control blocks 130a and 130b receive data from an external source (e.g., a chip testing unit) and control the data to be written to the memory array 110a and 110b, respectively, or control data from the memory array 110a and 110b, respectively, to be output in response to control signals /RAS, /CAS, and /WE, a clock signal CLK, and an address signal ADD, which are received from an external source.

The control blocks 130a and 130b can include a command decoder (not shown) which receives the control signals /RAS, /CAS, and /WE, the clock signal CLK, and the address signal ADD from an external source, decodes the signals, and generates internal command signals; combatable with the control blocks 130a and/or 130b; and a mode register set (MRS) circuit (not shown) which can set an internal mode register in response to a control signal for setting an operation mode of the semiconductor memory device 100 and/or the address signal ADD.

In embodiments of inventive concepts, the operation mode of the semiconductor memory device 100 can be separated into test and non-test modes. The MRS circuit can set the test mode in response to the control signal and/or the address signal ADD.

Each of the data input and output circuits 120a and 120b include a data input circuit and a data output circuit (not shown), which are connected with a data input/output terminal DQA or DQB. The data input circuit can be controlled by the control block 130a or 130b to receive data through the data input/output terminal DQA or DQB and write the data to the memory array 110a or 110b in a write operation. The data output circuit is controlled by the control block 130a or 130b to output data that is read from the memory array 110a or 110b through the data input/output terminal DQA or DQB in a read operation.

The memory chips 101, 102, 103, and 104 can individually and separately receive a signal which enables an independent operation of each memory chip, such as a chip selection signal /CS_A or /CS_B, and can receive other signals separately or jointly according to various embodiments. For example, the memory chips 101, 102, 103, and 104 can individually receive a chip selection signal /CS and a clock enable signal (not shown), thereby operate independently.

The clock signal CLK, the control signals /RAS, /CAS, and /WE, and the address signal ADD can be applied jointly to the memory chips 101, 102, 103, and 104.

Data output terminals of the first and second memory chips 101 and 102 can be connected in common to an external terminal, as illustrated in FIG. 2A. In detail, the terminals DQA and DQB of the respective first and second memory chips 101 and 102 can be connected in common to a terminal DQ. The other data output terminals of the first memory chip 101 can be also respectively connected with the other data output terminals of the second memory chip 102 and two corresponding data output terminals of the first and second memory chips 101 and 102 can be connected in common to a corresponding one of the external terminals.

In this case, the semiconductor memory device 100 does input a signal to or output a signal from two or more memory chips simultaneously. For instance, while the first memory chip 101 is outputting data through the terminal DQA, the second memory chip 102 cannot output data through the terminal DQB.

However, present inventive concepts are not restricted to these limitations. In an embodiment, the data input/output terminals of the respective first and second memory chips 101 and 102 can be separately connected to external terminals, respectively. In this case, while the first and second memory chips 101 and 102 can independently receive data or output data in the non-test mode of the semiconductor memory device 100, data input/output terminals of the first and second memory chips 101 and 102 can be connected in common to a terminal of a tester in the test mode of the semiconductor memory device 100.

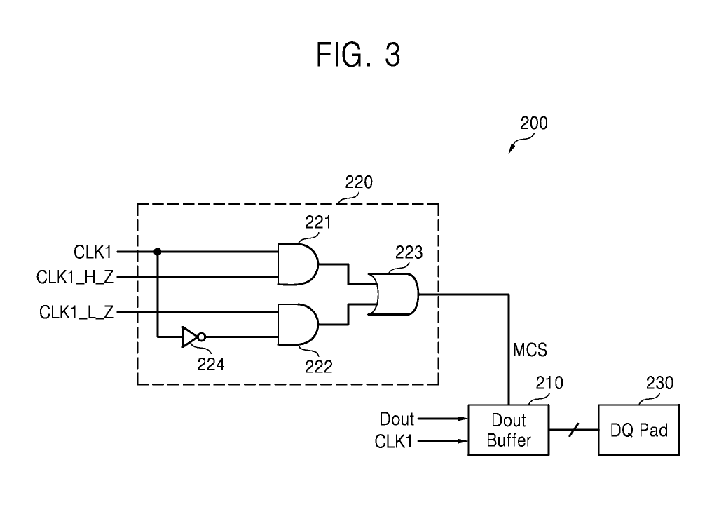

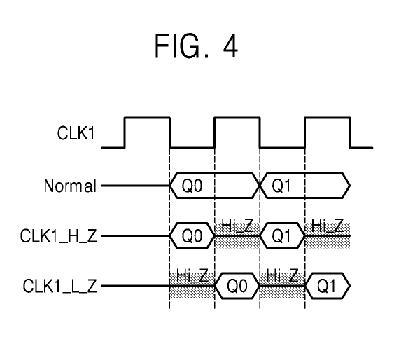

FIG. 3 is a diagram of the structure of a data output circuit 200 included in the data input and output block illustrated in FIG. 1 according to some embodiments of present inventive concepts. FIG. 4 is a timing chart showing the operation of the data output circuit 200 illustrated in FIG. 3. For clarity of the description, delay of elements (i.e., an inverter, an AND element, an OR element, etc.) is not considered.

Referring to FIGS. 3 and 4, the data output circuit 200 includes a data output buffer 210 and a data masking control circuit 220.

The data output buffer 210 outputs readout data Dout in response to a first clock signal CLK1 and a masking control signal MCS. The data masking control circuit 220 includes a first AND element 221, a second AND element 222, an OR element 223, and an inverter 224. The first AND element 221 performs an AND operation on the first clock signal CLK1 and a first masking signal CLK1_H_Z. The second AND element 222 performs an AND operation on an inverted signal of the first clock signal CLK1 and a second masking signal CLK1_L_Z.

The first clock signal CLK1 can be the clock signal CLK or a clock bar signal /CLK, which can be received from an external source of the semiconductor memory device 100, but is not restricted thereto. For instance, the first clock signal CLK1 can be an internal signal generated from the external clock signal CLK or clock bar signal /CLK. Alternatively, the first clock signal CLK1 can be a signal (e.g., a data strobe signal (DQS)) which is not used in the test mode, a special signal received from an external source, or an internally generated signal.

The first masking signal CLK1_H_Z can be a signal for masking high periods in clock cycles of the first clock signal CLK1 in which high periods alternate with low periods.

The second masking signal CLK1_L_Z can be a signal for masking low periods in the clock cycles of the first clock signal CLK1.

The OR element 223 performs an OR operation on an output signal of the first AND element 221 and an output signal of the second AND element 222 and outputs the masking control signal MCS according to these operations.

The data output buffer 210 outputs output data Q0 or Q1 to an output terminal 230 or puts the output terminal 230 into a state Hi_Z of in response to the masking control signal MCS.

For instance, when the masking control signal MCS is “1” (high level), the data output buffer 210 puts the output terminal 230 into the state of high impedance Hi_Z, so that the output data Q0 or Q1 is not transmitted to the output terminal 230. Accordingly, when the masking control signal MCS is “1”, the output data Q0 or Q1 can be masked.

In contrast, when the masking control signal MCS is “0” (low level), the data output buffer 210 transmits the output data Q0 or Q1 to the output terminal 230. When the masking control signal MCS is “0”, the output data Q0 or Q1 can be transmitted to the output terminal 230 without being masked.

When both of the first masking signal CLK1_H_Z and the second masking signal CLK1_L_Z are disabled to “0”, the masking control signal MCS is “0”. Subsequently, the data output buffer 210 operates in a normal mode in which it transmits the output data Q0 or Q1 to the output terminal 230 and does not mask the output data. As a result, the output data Q0 or Q1 is output throughout a full period (i.e., both high and low periods) of a cycle of the first clock signal CLK1.

Referring to FIG. 4, the operation of the data output circuit 200 performed when the first masking signal CLK1_H_Z is enabled to “1” and the second masking signal CLK1_L_Z is disabled to “0” is described below.

In an embodiment, the first masking signal CLK1_H_Z is enabled to “1” and the second masking signal CLK1_L_Z is disabled to “0”, and the masking control signal MCS can be in phase with the first clock signal CLK1. Since the output terminal 230 is in the state of high impedance Hi_Z in a period in which the masking control signal MCS is “1”, the output data Q0 or Q1 is transmitted to the output terminal 230 in only a low period of the first clock signal CLK1 and the output terminal 230 is in the state of high impedance Hi_Z in a high period of the first clock signal CLK1, as illustrated in FIG. 4.

In contrast, when the first masking signal CLK1_H_Z is disabled to “0” and the second masking signal CLK1_L_Z is enabled to “1”, the data output circuit 200 operates as follows. When the first masking signal CLK1_H_Z is disabled to “0” and the second masking signal CLK1_L_Z is enabled to “1”, the masking control signal MCS can be an inverted signal of the first clock signal CLK1. Since the output terminal 230 is in the state of high impedance Hi_Z in a period in which the masking control signal MCS is “1”, the output data Q0 or Q1 is output to the output terminal 230 in only a high period of the first clock signal CLK1 and the output terminal 230 is in the state of high impedance Hi_Z in a low period of the first clock signal CLK1, as illustrated in FIG. 4. Consequently, the data output circuit 200 transmits the output data Q0 or Q1 to the output terminal 230 only during a particular period (e.g., a high period) in a cycle of the first clock signal CLK1 and puts the output terminal 230 into the state of high impedance Hi_Z during the remaining period (e.g., a low period) in the cycle of the first clock signal CLK1 lest the output data Q0 or Q1 should be output.

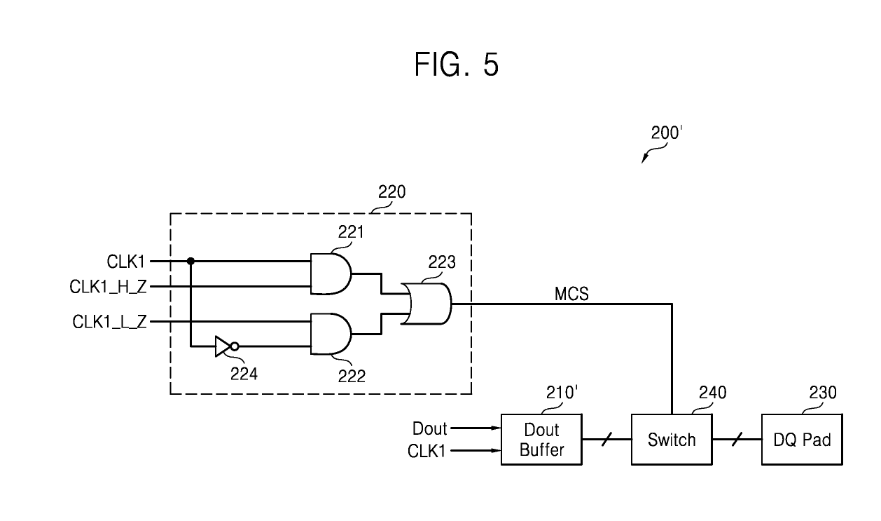

FIG. 5 is a diagram of the structure of a data output circuit 200′ according to other various embodiments of present inventive concepts.

The data output circuit 200′ includes a data output buffer 210′, the data masking control circuit 220, and a switch 240.

The switch 240 is positioned between the data output buffer 210′ and the output terminal 230 and is closed or opened in response to the masking control signal MCS. For example, in an embodiment, when the masking control signal MCS is “1” (high level), the switch 240 is opened and the output terminal 230 is put into a state of high impedance Hi_Z. When the masking control signal MCS is “0” (low level), the switch 240 transmits output data of the data output circuit 200′ to the output terminal 230.

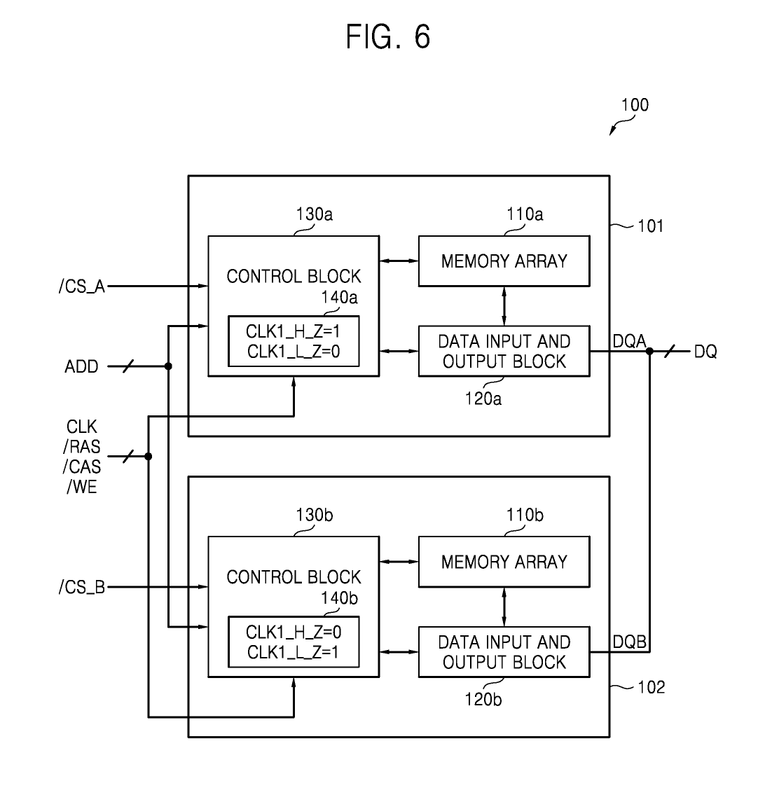

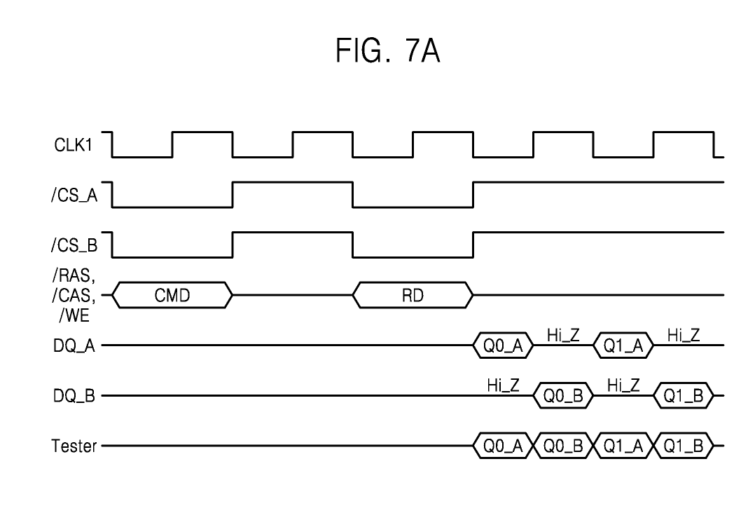

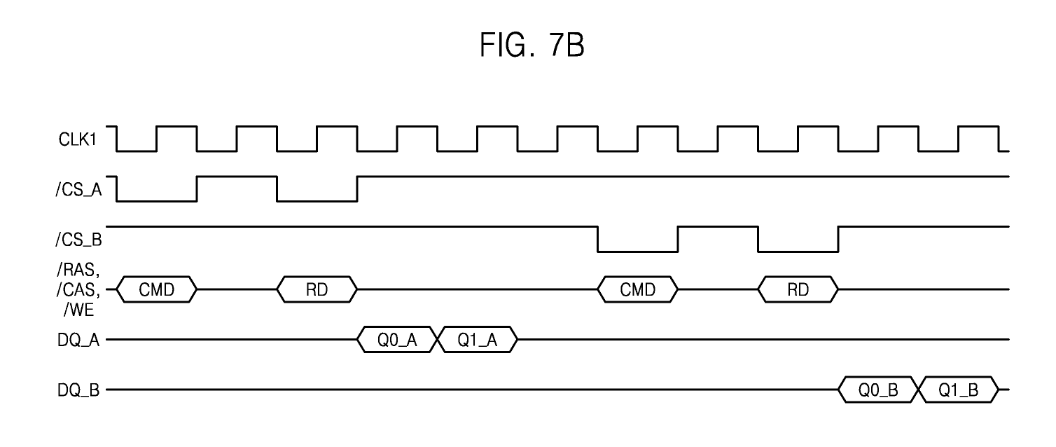

FIG. 6 is a detailed diagram of the structure of a semiconductor memory device 100 according to some embodiments of present inventive concepts. FIG. 7A is a timing chart of the operation of the semiconductor memory device 100 illustrated in FIG. 6.

Referring to FIGS. 6 and 7A, the first masking signal CLK1_H_Z of the first memory chip 101 and the second masking signal CLK1_L_Z of the second memory chip 102 are be set to “1”.

In an embodiment, the first and second chip selection signals /CS_A and /CS_B are simultaneously enabled wherein the first and second memory chips 101 and 102 may be selected for operation or testing simultaneously. When the first and second chip selection signals /CS_A and /CS_B are enabled, a read command RD can be applied concurrently to the first and second memory chips 101 and 102.

Each of the first and second memory chips 101 and 102 reads data from its memory array in response to the read command RD and transmits the data to an output terminal through a data output buffer (e.g., data output buffer 200 or 200′ such as shown in FIGS. 3 and 5). In accordance with embodiments of inventive concepts, the first masking signal CLK1_H_Z of the first memory chip 101 is 1, a first output terminal DQ_A of the first memory chip 101 is in the state of high impedance Hi_Z during high periods of the first clock signal CLK1 and data Q0_A and Q1_A are respectively output during only low periods of the first clock signal CLK1.

In addition, as a result of the second masking signal CLK1_L_Z of the second memory chip 102 being “1”, a first output terminal DQ_B of the second memory chip 102 is in the state of high impedance Hi_Z during the low periods of the first clock signal CLK1 and, subsequently, data Q0_B and Q1_B are respectively transmitted during only the high periods of the first clock signal CLK1.

Accordingly, the output data Q0_A and Q1_A of the first memory chip are alternately transmitted (e.g., to a tester) during the low periods, respectively, of the first clock signal CLK1 and the output data Q0_B and Q1_B of the second memory chip 101 are alternately transmitted during the high periods, respectively, of the first clock signal CLK1.

As described above, according to some embodiments of present inventive concepts, a cycle of the first clock signal CLK1 is divided into two periods, e.g., a high period and a low period. In an embodiment, data of a first memory chip is transmitted and an output terminal of a second memory chip is put into a state of high impedance during the high period and, during a low period, data of the second memory chip is transmitted and an output terminal of the first memory chip is put into the state of high impedance so that the data of the first memory chip and the data of the second memory chip are alternately transmitted in each clock cycle. Accordingly, the first and second memory chips are simultaneously selected for a read operation and/or a test operation.

Consequently, the first and second memory chips are tested concurrently, so that test time and cost are reduced.

FIG. 7B is a timing chart of the operation of a semiconductor memory device (not shown). A semiconductor memory device operating in accordance with FIG. 7B, for example, may not have a function of putting an output terminal into a state of high impedance during a partial period of a clock signal. Accordingly, output data, DQ_A and DQ_B, respectively, of each memory chip is transmitted during a full period of a cycle of the a clock signal CLK1.

Subsequently, when two or more memory chips are simultaneously selected to read data, output data of a first memory chip and output data of a second memory chip are transmitted simultaneously. Therefore, a testing device, for example, may require that each memory chip be tested independently and sequentially and/or additional testing units and outputs be used, adding expense and time.

For example, a first chip selection signal /CS_A may be enabled to select the first memory chip. The first chip selection signal /CS_A is enabled and the read command RD is applied to the semiconductor memory device. Then, the first memory chip reads data from a memory array in response to the read command RD and outputs the data to an output terminal through a data output buffer. As a result, data Q0_A or Q1_A is output to a first output terminal DQ_A of the first memory chip during a full period of a cycle of the first clock signal CLK1.

After data output of the first memory chip is completed, the second chip selection signal /CS_B is enabled to select the second memory chip. The second chip selection signal /CS_B is enabled and the read command RD is applied to the semiconductor memory device. Then, the second memory chip reads data from a memory array in response to the read command RD and outputs the data to an output terminal through a data output buffer. As a result, data Q0_B or Q1_B is output to a second output terminal DQ_B of the second memory chip during a full period of a cycle of the first clock signal CLK1.

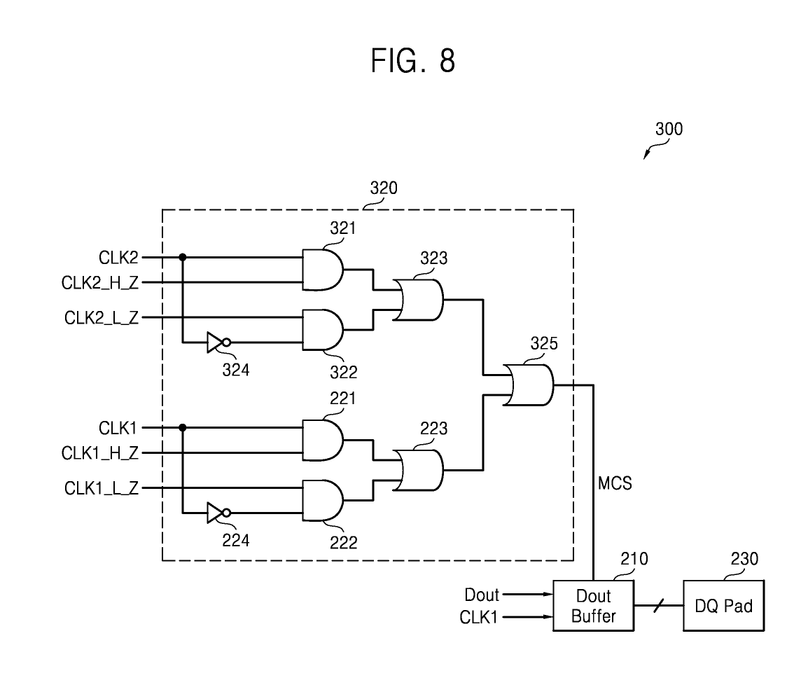

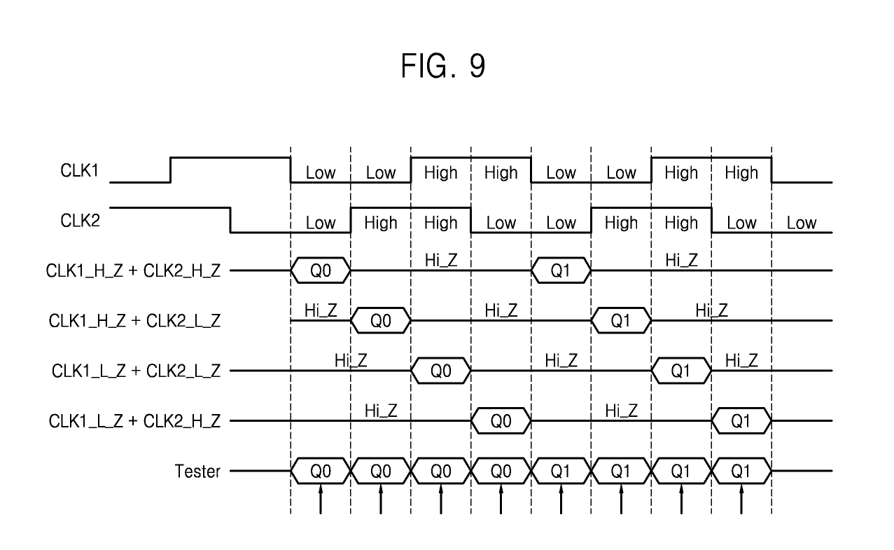

FIG. 8 is a diagram of the structure of a data output circuit 300 according to other embodiments of present inventive concepts. FIG. 9 is a timing chart of the operation of the data output circuit 300 illustrated in FIG. 8. For clarity of the description, delay of elements (i.e., an inverter, an AND element, an OR element, etc.) is not considered.

Referring to FIGS. 8 and 9, a data output circuit 300 includes the data output buffer 210 and a data masking control circuit 320 according to an embodiment of inventive concepts.

In an embodiment, the data output buffer 210 transmits a readout data Dout in response to a first clock signal CLK1 and a masking control signal MCS. The data masking control circuit 320 includes first through fourth AND elements 221, 222, 321, and 322; OR elements 223, 323, and 325; and inverters 224 and 324. In an embodiment, the first AND element 221 performs an AND operation on the first clock signal CLK1 and a first masking signal CLK1_H_Z, and the second AND element 222 performs an AND operation on an inverted signal of the first clock signal CLK1 and a second masking signal CLK1_L_Z. The third AND element 321 performs an AND operation on a second clock signal CLK2 and a third masking signal CLK2_H_Z, and the fourth AND element 322 performs an AND operation on an inverted signal of the second clock signal CLK2 and a fourth masking signal CLK2_L_Z.

In embodiments of inventive concepts, the first clock signal CLK1 can be the clock signal CLK or a clock bar signal /CLK, which is received from an external source of a semiconductor memory device or can be an internal signal generated in response to the external clock signal CLK or clock bar signal /CLK. Alternatively, the first clock signal CLK1 can be a signal (e.g., a data strobe signal (DQS)) which is not used in a test mode such as, for example, a special signal received from an external source, or an internally generated signal.

In an embodiment, the second clock signal CLK2 can be a signal that has a predetermined phase difference (e.g., a 90-degree phase difference) from the first clock signal CLK1.

In an embodiment, the OR element 223 performs an OR operation on an output signal of the first AND element 221 and an output signal of the second AND element 222. In addition, the OR element 323 performs an OR operation on an output signal of the third AND element 321 and an output signal of the fourth AND element 322. In addition, the OR element 325 performs an OR operation on an output signal of the OR element 223 and an output signal of the OR element 323 and outputs the masking control signal MCS.

The data output buffer 210 transmits output data Q0 or Q1 to the output terminal 230 or put the output terminal 230 into a state of high impedance Hi_Z in response to the masking control signal MCS.

In an embodiment, when the masking control signal MCS is “1” (high level), the data output buffer 210 puts the output terminal 230 into the state of high impedance Hi_Z, so that the output data Q0 or Q1 is not transmitted to the output terminal 230. Accordingly, when the masking control signal MCS is “1”, the output data Q0 or Q1 can be masked.

While the masking control signal MCS is “0” (low level), the data output buffer 210 transmits the output data Q0 or Q1 to the output terminal 230. While the masking control signal MCS is “0”, the output data Q0 or Q1 can be transmitted to the output terminal 230 without being masked.

Referring particularly to FIG. 9, while the first and third masking signals CLK1_H_Z and CLK2_H_Z are enabled to “1”, the output data Q0 or Q1 is transmitted to the output terminal 230 only during a period in which both of the first and second clock signals CLK1 and CLK2 are low (e.g., the first clock signal CLK1 has a phase of 0 to 90 degrees) and the output terminal 230 is put into the state of high impedance Hi_Z during a period in which at least one of the first and second clock signals CLK1 and CLK2 is high, as illustrated in FIG. 9.

While the first and fourth masking signals CLK1_H_Z and CLK2_L_Z are enabled to “1”, the output data Q0 or Q1 is transmitted to the output terminal 230 only during a period in which the first clock signal CLK1 is low and the second signal CLK2 is high (e.g., the first clock signal CLK1 has a phase of 90 to 180 degrees) and the output terminal 230 is put into the state of high impedance Hi_Z during the otherwise period.

While the second and fourth masking signals CLK1_L_Z and CLK2_L_Z are enabled to “1”, the output data Q0 or Q1 is transmitted to the output terminal 230 only during a period in which both of the first and second clock signals CLK1 and CLK2 are high (e.g., the first clock signal CLK1 has a phase of 180 to 270 degrees) and the output terminal 230 is put into the state of high impedance Hi_Z during a period in which at least one of the first and second clock signals CLK1 and CLK2 is low, as illustrated in FIG. 9.

While the second and third masking signals CLK1_L_Z and CLK2_H_Z are enabled to “1”, the output data Q0 or Q1 is transmitted to the output terminal 230 only during a period in which the first clock signal CLK1 is high and the second signal CLK2 is low (e.g., the first clock signal CLK1 has a phase of 270 to 360 degrees) and the output terminal 230 is put into the state of high impedance Hi_Z during the otherwise period.

Consequently, in response to a set of masking signals, the data output circuit 300 transmits the output data Q0 or Q1 to the output terminal 230 only during a particular period (e.g., one of four periods) in a cycle of a clock signal and puts the output terminal 230 into the state of high impedance Hi_Z during the remaining periods (e.g., the other three periods) in the cycle of the clock signal lest the output data Q0 or Q1 should be transmitted.

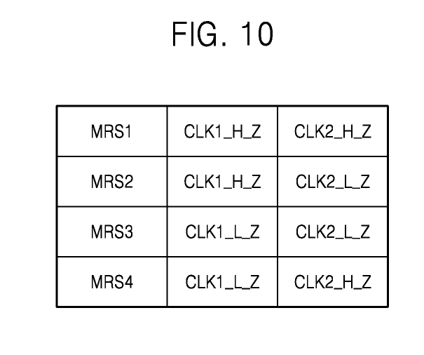

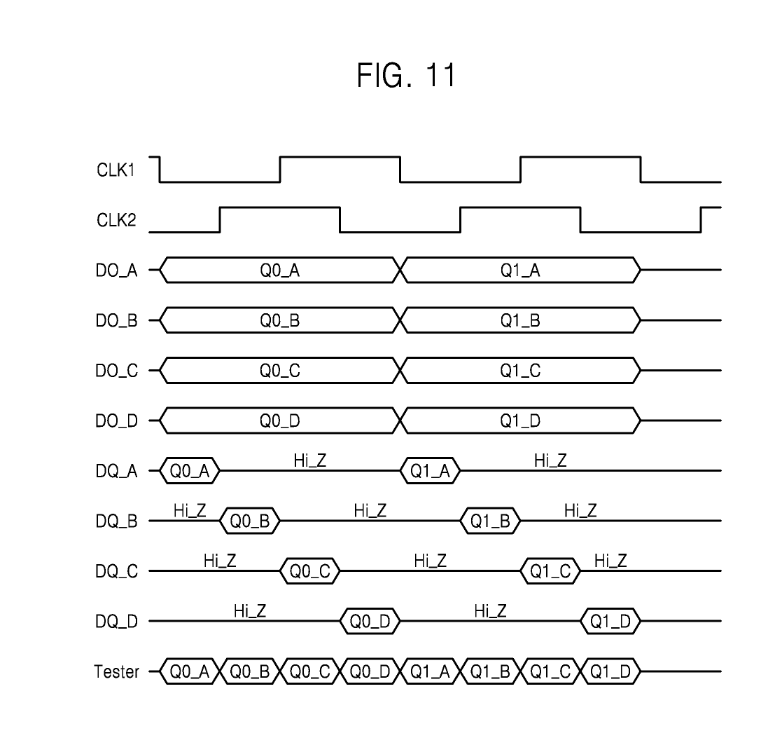

FIGS. 10 and 11 are a table and a timing chart, respectively, illustrating the operation of a semiconductor memory device, which includes four memory chips, according to other embodiments of present inventive concepts. In particular, FIG. 10 shows mode register sets MRS1, MRS2, etc. . . . for each of a first through fourth memory chips 101 through 104, respectively, such as illustrated in FIG. 2B.

Referring to FIG. 10, the first masking signal CLK1_H_Z and the third masking signal CLK2_H_Z can be set to “1” for selecting the first memory chip 101, the first masking signal CLK1_H_Z and the fourth masking signal CLK2_L_Z can be set to “1” for selecting the second memory chip 102, the second masking signal CLK1_L_Z and the fourth masking signal CLK2_L_Z can be set to “1” for selecting the third memory chip 103, and the second masking signal CLK1_L_Z and the third masking signal CLK2_H_Z can be set to “1” for selecting the fourth memory chip 104.

In an embodiment, first through fourth chip selection signals /CS_A, /CS_B, /CS_C, and /CS_D (not shown) can be simultaneously enabled. At this time, the first through fourth memory chips 101 through 104 can be selected simultaneously. In a state where the first through fourth memory chips 101 through 104 are all selected, the read command RD can be applied concurrently to the first through fourth memory chips 101 through 104.

Each of the first through fourth memory chips 101 through 104 read data from a memory array in response to the read command RD and outputs the data to an output terminal (DQ_A, . . . DQD) through a data output buffer 210 (DO_A, . . . DOD) in accordance with the masking signal arrangements.

While the first and third masking signals CLK1_H_Z and CLK2_H_Z, respectively, are set to “1” for the first memory chip 101, such as illustrated in FIG. 11, data read from the memory array of the first memory chip 101 is transmitted to a data output buffer DOA throughout the full period of a cycle of the first clock signal CLK1, however, output data Q0_A or Q1_A is transmitted to an output terminal DQ_A only during that period in which both of the first and second clock signals CLK1 and CLK2 are low (e.g., when the first clock signal CLK1 has a phase of 0 to 90 degrees), while the output terminal DQ_A is put into the state of high impedance Hi_Z during the other periods of the cycle.

While the first and fourth masking signals CLK1_H_Z and CLK2_L_Z, respectively, are set to “1” for the second memory chip 102, such as illustrated in FIG. 11 and output data Q0_B or Q1_B is transmitted to an output terminal DQ_B only during that period in which the first clock signal CLK1 is low and the second clock signal CLK2 is high (e.g., when the first clock signal CLK1 has a phase of 90 to 180 degrees), while the output terminal DQ_B is put into the state of high impedance Hi_Z during the other periods.

Similarly, when selecting the third memory chip 103, output data Q0_C or Q1_C is transmitted to an output terminal DQ_C only during that period in which both of the first and second clock signals CLK1 and CLK2 are high (e.g., when the first clock signal CLK1 has a phase of 180 to 270 degrees), while the output terminal DQ_C is put into the state of high impedance Hi_Z during a periods in which at least one of the first and second clock signals CLK1 and CLK2 is low.

When the fourth memory chip 104 is selected, output data Q0_D or Q1_D is transmitted to an output terminal only DQ_D during that period in which the first clock signal CLK1 is high and the second signal CLK2 is low (e.g., when the first clock signal CLK1 has a phase of 270 to 360 degrees) while the output terminal is put into the state of high impedance Hi_Z during the other periods.

In an embodiment, the output data Q0_A of the first memory chip 101, the output data Q0_B of the second memory chip 102, the output data Q0_C of the third memory chip 103, and the output data Q0_D of the fourth memory chip 104 can be read by a tester during a single clock cycle and then the subsequent output data Q1_A of the first memory chip 101, the subsequent output data Q1_B of the second memory chip 102, the subsequent output data Q1_C of the third memory chip 103, and the subsequent output data Q1_D of the fourth memory chip 104 can be read by the tester during a subsequent clock cycle.

As described above, according to the current embodiments of present inventive concepts, each cycle of the first clock signal CLK1 can be divided into four periods (e.g., a period of 0 to 90 degrees, a period of 90 to 180 degrees, a period of 180 to 270 degrees, and a period of 270 to 360 degrees) and data of only a particular memory chip is transmitted during a particular period while the output terminals of the other respective memory chips are put into to a state of high impedance, so that output data of the respective first through fourth memory chips can be sequentially transmitted during each clock cycle.

In previously described embodiments of present inventive concepts, each cycle of the first clock signal CLK1 is shown particularly divided into two or four periods, embodiments of present inventive concepts can be divided into additional periods. For example, in an embodiment, at least two clock signals having a phase difference from each other can be combined. For example, each cycle of a first clock signal among the at least two clock signals can be divided into any other number of (e.g., 3, 5, 6, 7, 8, etc) periods, and output data can be transmitted to an output terminal only during a particular period of each cycle of a first clock signal while the other output data will not be transmitted through an output terminal that is, for example, put into a state of high impedance during that particular period. Similarly, the other periods of each cycle can be configured so that other corresponding output terminals operate during those periods.

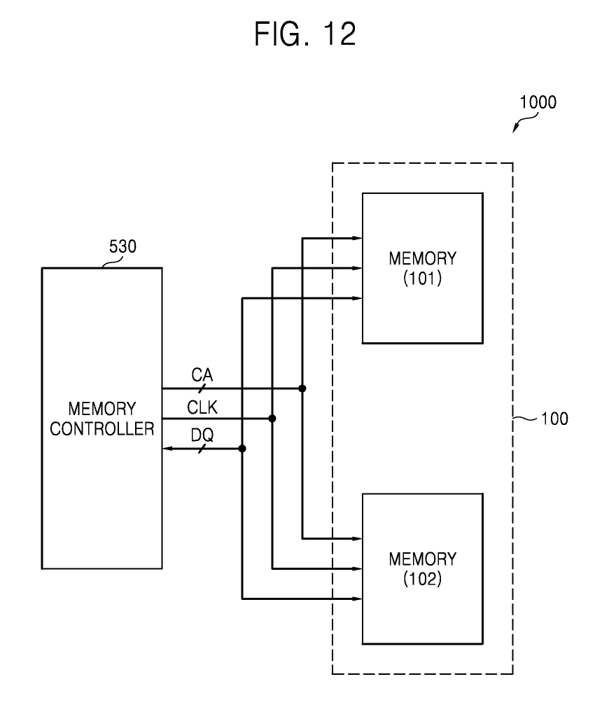

FIG. 12 is a schematic diagram of a memory system 1000 according to some embodiments of present inventive concepts. Referring to FIG. 12, the memory system 1000 includes a memory controller 530 and the memory device 100. The memory controller 530 can transmit a signal CA to the memory device 100 to perform an operation such as writing data to the memory device 100 or reading data from the memory device 100. The signal CA can include the control signals /RAS, /CAS, /WE and the address signal ADD, such as have been described above. When receiving a write command or a read command from the memory controller 500, the memory device 100 can perform input/output of data DQ using a clock signal CLK.

A memory device including a plurality of memory chips according to some embodiments of present inventive concepts can include, for example, an unbuffered dual in-line memory module (UDIMM), a registered dual in-line memory module (RDIMM), or a fully buffered dual in-line memory module (FBDIMM).

According to some embodiments of present inventive concepts, each cycle of a clock signal is divided into a plurality of periods (e.g., a high period and a low period) and data for a particular chip is transmitted only during a particular period such as, for example, while output terminals for other chips are put into a state of high impedance. Therefore, the number of memory chips that can be tested concurrently is increased. As a result, test and manufacturing time of a semiconductor memory device including a plurality of memory chips can be reduced.

While present inventive concepts have been particularly shown and described with reference to exemplary embodiments thereof, it will be understood by those of ordinary skill in the art that various changes in forms and details can be made therein without departing from the spirit and scope of inventive concepts as defined by the following claims.

1. A semiconductor memory device comprising:
a memory cell array comprising a plurality of memory cells each of which stores at least one bit of data;
an output terminal configured to transmit output data; and
a data output circuit configured to be connected with the output terminal, to divide a cycle of a clock signal into at least two periods, to transmit the output data to the output terminal only during a particular period of the at least two periods, and to put the output terminal into a state of high impedance during the remaining periods other than the particular period of the at least two periods.

2. The semiconductor memory device of claim 1, wherein the data output circuit comprises:
a data masking control circuit configured to generate a masking control signal which is enabled during the particular period and is disabled during the remaining period in response to the clock signal and a masking signal; and
a data output buffer configured to transmit the output data to the output terminal or put the output terminal into the state of high impedance in response to the clock signal and the masking control signal.

3. The semiconductor memory device of claim 1, wherein the data output circuit comprises:
a data masking control circuit configured to generate a masking control signal which is enabled during the particular period and is disabled during the remaining period in response to the clock signal and a masking signal;
a data output buffer configured to transmit the output data to the output terminal in response to the clock signal; and
a switch configured to be positioned between the data output buffer and the output terminal and to be closed or opened in response to the masking control signal,
wherein if the switch is closed the switch transmits the output data to the output terminal, otherwise the switch puts the output terminal into the state of high impedance.

4. The semiconductor memory device of claim 2, wherein the masking signal comprises a first masking signal and a second masking signal, and
the data masking control circuit comprises:
a first AND element configured to perform an AND operation on the clock signal and the first masking signal;
a second AND element configured to perform an AND operation on an inverted signal of the clock signal and the second masking signal; and
a first OR element configured to perform an OR operation on an output signal of the first AND element and an output signal of the second AND element and to output the mask control signal.

5. The semiconductor memory device of claim 2, wherein the clock signal is a first clock signal,
the masking signal comprises first, second, third and fourth masking signals, and
the data masking control circuit comprises:
a first AND element configured to perform an AND operation on the clock signal and the first masking signal;
a second AND element configured to perform an AND operation on an inverted signal of the clock signal and the second masking signal;
a first OR element configured to perform an OR operation on an output signal of the first AND element and an output signal of the second AND element;
a third AND element configured to perform an AND operation on a second clock signal and the third masking signal;
a fourth AND element configured to perform an AND operation on an inverted signal of the second clock signal and the fourth masking signal;
a second OR element configured to perform an OR operation on an output signal of the third AND element and an output signal of the fourth AND element; and
a third OR element configured to perform an OR operation on an output signal of the first OR element and an output signal of the second OR element and to output the mask control signal.

6. The semiconductor memory device of claim 2, further comprising a mode register set (MRS) circuit configured to set the masking signal.

7. The semiconductor memory device of claim 6, wherein data output circuit transmits the output data to the output terminal only during the particular period and puts the output terminal into the state of high impedance during the remaining periods in response to the masking control signal in a test mode and the data output circuit transmits the output data to the output terminal during a full period of a cycle of the clock signal in a non-test mode.

8. A semiconductor memory device comprising:
a plurality of semiconductor chips; and
an external terminal configured to transmit a signal output from each of the semiconductor chips to an external circuit,
wherein each of the semiconductor chips comprises:
an output terminal configured to transmit output data; and
a data output circuit configured to be connected with the output terminal, to divide a cycle of a clock signal into a plurality of periods, to transmit the output data to the output terminal only during a particular period among the plurality of periods, and to put the output terminal into a state of high impedance during the remaining periods other than the particular period among the plurality of periods.

9. The semiconductor memory device of claim 8, wherein the output terminals of the respective semiconductor chips are connected in common with at least one of the external terminal or independent external output terminals.

10. The semiconductor memory device of claim 9, wherein each of the semiconductor chips further comprises a mode register set (MRS) circuit configured to set a test mode, and
the data output circuit transmits the output data to the output terminal only during the particular period and puts the output terminal into the state of high impedance during the remaining period in response to a masking control signal in the test mode and the data output circuit transmits the output data to the output terminal during a full period of a cycle of the clock signal in a non-test mode.

11. The semiconductor memory device of claim 9, wherein the data output circuit comprises:
a data masking control circuit configured to generate a masking control signal which is enabled during the particular period and is disabled during the remaining period in response to the first clock signal and a masking signal; and
a data output buffer configured to transmit the output data to the output terminal or put the output terminal into the state of high impedance in response to the clock signal and the masking control signal.

12. The semiconductor memory device of claim 9, wherein the semiconductor chips comprise first through n-th memory chips where “n” is 2 or an integer greater than 2, and a data output circuit of each of the first through n-th memory chips transmits data of a memory chip, which comprises the data output circuit, only during a particular period among first through n-th periods into which each cycle of the clock signal is divided and puts an output terminal of the memory chip into the state of high impedance during the remaining periods.

13. The semiconductor memory device of claim 12, wherein:
“n” is 2 and each of the clock cycles is divided into a first and second period;
a data output circuit of the first memory chip transmits data of the first memory chip only during the first period of each cycle of the clock signal; and
a data output circuit of the second memory chip transmits data of the second memory chip only during the second period of each cycle of the clock signal.

14. The semiconductor memory device of claim 12, wherein:
“n” is 4 and each of the clock cycles is divided into first through fourth periods;
a data output circuit of the first memory chip transmits data of the first memory chip only during the first period of each cycle of the clock signal;
a data output circuit of the second memory chip transmits data of the second memory chip only during the second period of each cycle of the clock signal;
a data output circuit of the third memory chip transmits data of the third memory chip only during the third period of each cycle of the clock signal; and
a data output circuit of the fourth memory chip transmits data of the fourth memory chip only during the fourth period of each cycle of the clock signal.

15. A test system comprising:
the semiconductor memory device of claim 8; and
a tester configured to receive data output through the external terminal of the semiconductor memory device and compare the data with reference data to test the semiconductor memory device.

16. A memory system comprising:
the semiconductor memory device of claim 8; and
a memory controller configured to control the semiconductor memory device.

17. A method of testing a semiconductor memory device which includes a plurality of memory chips, the method comprising the operations of
dividing a cycle of a clock signal into a plurality of periods; and
transmitting output data of each of the memory chips to an output terminal of each memory chip only during a particular period among the plurality of periods and putting the output terminal into a state of high impedance during the remaining periods other than the particular period among the plurality of periods.

18. The method of claim 17, wherein the plurality of periods comprises two periods including a first period and second period, and
wherein the operation of transmitting the output data and putting the output terminal into the state of high impedance comprises:
transmitting output data of a first memory chip only during the first period of each cycle of the clock signal; and
transmitting output data of a second memory chip only during the second period of each cycle of the clock signal.

19. The method of claim 17, wherein the plurality of periods comprises four periods including first through fourth periods, and
wherein the operation of transmitting the output data and putting the output terminal into the state of high impedance comprises:
transmitting output data of a first memory chip only during the first period of each cycle of the first clock signal;
transmitting output data of a second memory chips only during the second period of each cycle of the clock signal;
transmitting output data of a third memory chip only during the third period of each cycle of the clock signal; and
transmitting output data of a fourth memory chip only during the fourth period of each cycle of the clock signal.

20. The method of claim 17, further comprising a tester receiving data output through an external terminal of the semiconductor memory device and comparing the data with reference data.

21-27. (canceled)
